(19) United States
(12) Patent Application Publication
(10) Pub. No.: US 2006/0088072 A1
(43) Pub. Date: Apr. 27, 2006

(54) Semiconductor laser apparatus

(75) Inventors: Toshiro Hayakawa, Kanagawa-ken (JP); Hideki Asano, Kanagawa-ken (JP); Shinichi Nagahama, Anan-shi (JP); Yuji Matsuyama, Anan-shi (JP); Katsutoshi Komoto, Anan-shi (JP)

Correspondence Address: SUGHRUE MION, PLLC, 2100 PENNSYLVANIA AVENUE, N.W., SUITE 800, WASHINGTON, DC, 20037, US

(73) Assignees: FUJI PHOTO FILM CO., LTD.; NICHIA CORPORATION

(21) Appl. No.: 11/255,932

(22) Filed: Oct. 24, 2005

(30) Foreign Application Priority Data
Oct. 22, 2004 (JP) 308285/2004

(51) Int. Cl. H01S 5/00

(52) U.S. Cl. 372/45.01; 372/46.01; 372/44.01

(57) ABSTRACT

A GaN system stripe type semiconductor laser having an index guiding structure, and producing higher mode or multimode oscillation in the transverse mode, which is constructed such that the horizontal beam radiation angle of each of a plurality of the emitting regions is minimized to provide a high luminance focused beam. In a GaN system stripe type semiconductor laser, which has an index guiding structure constituted, for example, by a ridge structure formed on a p-GaN cap layer 28 and p-Al_{0.1}Ga_{0.9}N clad layer 27 with the width W2, and produces higher mode or multimode oscillation in the transverse mode, the effective index difference Δn between the central region of the stripe and outside of the stripe is set not greater than 1.5×10⁻².

### BACKGROUND OF THE INVENTION

1. Field of the Invention

The present invention relates generally to a semiconductor laser device. More specifically, the present invention is directed to a semiconductor laser device constructed to combine laser beams emitted from GaN system semiconductor laser chips, each having a stripe width of not less than 3 μm, and producing higher mode or multimode oscillation in the transverse mode.

2. Description of the Related Art

AlInGaN system, which is III-V nitride family, semiconductor lasers have been the center of attention to be used as a light source that emits light at wavelength in the short wavelength region of not greater than 600 nm. GaN system materials, including AlInGaN, have outstanding characteristics for fabricating semiconductor light emitting devices that emit light in the blue and green wavelength regions as described, for example, in “High-Brightness InGaN Blue, Green and Yellow Light-Emitting Diodes with Quantum Well Structures” by Shuji Nakamura, et al., Japanese Journal of Applied Physics, Vol. 34, No. 7A, 1995, pp. L797-799. Recently, technical efforts have been made for developing semiconductor lasers that oscillate at short wavelengths in the region from 360 to 500 nm using such materials and putting them into practical use.

Such semiconductor lasers have shorter oscillation wavelengths, and are capable of producing markedly smaller light spots than those produced by the currently available semiconductor lasers having the shortest wavelength of 630 nm. Thus, they are most expected for use in the light source applications of high-density optical disk memories. In addition, a light source with a short wavelength of not greater than 450 nm is crucial as the light source of digital imaging devices used in the field of printing or the like, in which photosensitive materials having high sensitivities in the shorter wavelength region are used. Further, a semiconductor laser that oscillates at a wavelength of 405 nm has been put into practical use as the exposing light source of CTP (computer to plate) that uses a photopolymer material. In these applications, an optically superior single peak Gaussian beam is required. Thus, the use of high-quality fundamental transverse mode lasers is indispensable for these applications.

In order to realize fundamental transverse mode oscillation, it is necessary to stabilize the waveguide mode using the index-guiding structure of the device. For that purpose, the index difference of the index-guiding structure, that is, the effective index difference Δn between the central region of the stripe and outside of the stripe is generally set at a value in the range from 5×10⁻³ to 1×10⁻². In addition, a very narrow stripe width of 2 μm or less is required in order to realize fundamental transverse mode oscillation. For this reason, the optical density at the end face of the device becomes very high. For example, in a 50 mW semiconductor device used as the recording light source of optical disks, the optical density at the end face of the device amounts to as high as approximately 5MW/cm². Thus, in the GaN system semiconductor laser that oscillates in the fundamental transverse mode, the upper limit of continuous power that may be obtained from a single stripe, with practical reliability of several thousand to over ten thousand hours, is thought to be in the range around from 100 to 200 mW.

Further, in order to obtain a higher optical power, it is necessary to cause the device to oscillate in higher transverse mode or transverse multimode by providing a broader stripe width. In practice, as such high power semiconductor lasers, red and infrared broad stripe semiconductor lasers that provide high powers in the range from 0.5 to 5 W with the stripe width in the range around from 50 to 2000 μm are widely used in the fields of solid-state laser excitation, welding, soldering, medicine, and the like.

The GaN system semiconductor laser described above has a potentiality to replace the red and infrared semiconductor lasers used in these applications because of its shorter wavelength. The GaN system semiconductor laser also has a potentiality to be applied to material modification through photochemical reactions and other industrial fields because of its high photon energy. In order to realize such applications, improvement in the performance of the device that oscillates in higher transverse mode or transverse multimode is crucial. In particular, a high power light source is used for obtaining light as energy, but it is important to increase luminance, not just the power. In the GaN system semiconductor laser, a high reliability is realized by partially decreasing the crystal defect (dislocation) density using the transverse growth, so that there is a limitation for broadening the stripe width with the high grade crystallinity being maintained under present circumstances. Recently, a wholly low dislocation density GaN substrate is realized, but it is extremely expensive compared with a general sapphire substrate. Therefore, significant cost and price reductions for the GaN substrate need to be realized before being put into general purpose use.

Under the circumstances described above, in order to realize a high power and high luminance laser device, that is, a laser device with a high laser power per unit area, it is effective to combine and focus laser beams emitted from a plurality of emitting regions. FIG. 4 schematically shows a general semiconductor device that employs a beam combining and focusing system. In the semiconductor laser device, a plurality of semiconductor laser chips LD1 to LD5 is integrated. The laser beams B1 to B5 emitted from the laser chips LD1 to LD5 are collimated by collimating lenses C1 to C5, each having the focal length of f1 and numerical aperture of NA1, then they are combined and focused by a condenser lens D having the focal length of f2 and numerical aperture of NA2. FIG. 5 shows a semiconductor laser device, in which laser beams B1 to B5 emitted from a semiconductor laser array LA, which is produced by integrating a plurality of emitting regions on a single semiconductor chip, are combined and focused.

In the illustrated beam-combining laser light sources, a plurality of near-field patterns ranging in a direction parallel to the junction surface is combined. The magnification m of the optical system is expressed as m=f2/f1. Now, letting W1 be the width of the near-field pattern of the semiconductor laser, then the width W2 of the focused spot in the direction parallel to the junction surface may be expressed as W2=m×W1. Letting NA2 be the divergence angle of the focused beam, then the luminance of the output beam may be defined based on the NA2 (product of the spot diameter and the divergence angle). Meanwhile, in order for the collimated light comprising n beams to be focused through the condenser lens, the relationship of (n/m)×NA1≦NA2 needs to be satisfied. Therefore, for a given optical system, in order to obtain a higher power and higher luminance by increasing the number of beams n to be combined, the radiation angle (numerical aperture of the collimating lens) NA1 of the output beam from the semiconductor laser needs to be minimized.

Minimizing the horizontal beam radiation angle, that is, the radiation angle in the direction parallel to the junction surface of the GaN system semiconductor laser device is widespread demand, not just for increasing the number of beams n to be combined as described above.

### SUMMARY OF THE INVENTION

In view of the circumstances described above, it is an object of the present invention to provide a semiconductor apparatus capable of combining higher number of laser beams emitted from semiconductor laser chips that may be fabricated to have a small horizontal beam radiation angle, and producing a high power and high luminance combined beam.

Laser chips comprising a semiconductor laser apparatus of the present invention are GaN system stripe type semiconductor lasers, each having an index guiding structure, and producing higher mode or multimode oscillation in the transverse mode, wherein the effective index difference Δn between the central region of the stripe and outside of the stripe is not greater than 1.5×10⁻².

Preferably, the effective index difference Δn is in the range of 5×10⁻³≦Δn≦1.5×10⁻², and more preferably in the range of 5×10⁻³≦Δn≦1×10⁻².

Preferably, the stripe width of the semiconductor lasers constructed in the manner as described above is not less than 5 μm.

As for the index-guiding structure, either a ridge waveguide structure or an inner stripe type waveguide structure may be employed favorably.

The semiconductor lasers, each having the structure described above and constituting the structural requirement of the present invention, may be produced as individual chips, each having a single stripe structure thereon, or as a semiconductor laser array produced by forming a plurality of stripe structures on a single semiconductor chip with each of the luminous points thereof being aligned substantially in a straight line in a direction parallel to the junction surface.

Meanwhile, a semiconductor laser apparatus of the present invention is a beam-combining laser apparatus using individual semiconductor lasers, each comprising a single stripe structure formed on a single chip, the apparatus comprising:

a plurality of the semiconductor laser chips arranged such that each of the luminous points thereof is aligned substantially in a straight line in a direction parallel to the junction surface;

a plurality of collimating lenses, each for collimating each of the laser beams emitted from each of the semiconductor laser chips; and

a condenser lens for focusing a plurality of the laser beams transmitted through the collimating lenses on a substantially common point.

Another semiconductor laser apparatus of the present invention is a beam-combining laser apparatus using a semiconductor laser chip produced as the semiconductor laser array described above, the apparatus comprising:

a single or a plurality of the semiconductor laser chips;

a plurality of collimating lenses, each for collimating each of the laser beams emitted from the semiconductor laser chip or chips; and

a condenser lens for focusing a plurality of the laser beams transmitted through the collimating lenses on a substantially common point.

Unlike semiconductor lasers that oscillate in fundamental transverse mode, in which the radiation angle may be determined by the waveguide design, for semiconductor lasers having a broader stripe width, and oscillate in transverse multimode, including higher transverse mode, it has been thought that the beam radiation angle may not be controlled. In this respect, a detailed description will be provided by way of specific examples herein below.

The inventors of the present invention created various sample devices of broad stripe multimode semiconductor lasers with 808 nm oscillation wavelength shown in FIG. 6 to find out conditions that may have decisive influences on the beam radiation angle. The semiconductor laser shown in FIG. 6 includes: an n-GaAs substrate 1 (Si=2×10¹⁸ cm⁻³ doped); an n-GaAs buffer layer 2 (Si=1×10¹⁸ cm⁻³ doped, 0.5 μm thickness); an n-Al_{0.63}Ga_{0.37}As clad layer 3 (Si=1×10¹⁸ cm⁻³ doped, 1 μm thickness); an undoped SCH active layer 4; a p-Al_{0.63}Ga_{0.37}As clad layer 5 (Zn=1×10¹⁸ cm⁻³ doped, 1 μm thickness); a p-GaAs cap layer 6 (Zn=2×10¹⁹ cm⁻³ doped, 0.3 μm thickness); an SiO₂ insulation film 7; a p-side electrode 8 (Ti/Pt/Au); and n-side electrode 9. The undoped SCH active layer 4 includes: an In_{0.48}Ga_{0.52}P optical waveguide layer (undoped, layer thickness Wg=0.1 μm); an In_{0.13}Ga_{0.87}As_{0.75}P_{0.25} quantum well layer (undoped, 10 nm); and an In_{0.48}Ga_{0.52}P optical waveguide layer (undoped, layer thickness Wg=0.1 μm).

The semiconductor lasers in this example have a mesa stripe structure with the bottom width W3. Here, five different samples having the stripe width W3 of 10, 15, 20, 25, and 55 μm respectively were created. In addition, three different samples having the effective index differences Δn between the central region of the stripe and outside of the stripe of 5×10⁻³, 7×10⁻³, and 1.4×10⁻² respectively were also created. These samples were created by changing the after-etching residual thickness t1 of the p-Al_{0.63}Ga_{0.37}As clad layer 5 in the etching region outside of the mesa stripe to control the effective index difference Δn. In the conventional infrared semiconductor lasers, the beam radiation angle does not change in the Δn region of 9×10⁻⁷ and greater where stable index-guiding is obtained, so that the Δn was set rather large, for example, at 2×10⁻² or greater. The semiconductor lasers oscillated at room temperature with the threshold current of approximately 100 mA at a wavelength of approximately 808 nm.

The relationship between the horizontal beam radiation angle, that is, the beam radiation angle (full width at half maximum) on a plane which is parallel to the junction surface, and effective index difference Δn was obtained using the sample devices, and the result is shown in FIG. 7. Further, the relationship between the horizontal beam radiation angle (full width at half maximum) and stripe width W3 was also obtained using the sample devices, and the result is shown in FIG. 8.

As shown in FIG. 7, in these infrared broad stripe transverse multimode semiconductor lasers, the beam radiation angle is substantially constant independent of the effective index difference Δn in the stable index-guiding region of Δn=7×10⁻³ and greater. This indicates that the transverse mode, that is, the fundamental spatial frequency of the near-field pattern is controlled by the characteristics of the active region, which is a gain medium, regardless of the boundary conditions of the optical waveguide. In FIG. 7, the beam radiation angle is decreased where Δn=5×10⁻³. In the present example, however, the transverse mode was not stabilized due to the dependency of the transverse mode on the optical power, and index-guiding was excessively unstable for practical use due to decrease in the refractive index arising from the plasma effect caused by the carrier injected in the active layer.

On the other hand, the dependency of the beam radiation angle on the stripe width shown in FIG. 8 indicates that the beam radiation angle is maximal at the stripe width W3 of approximately 20 μm, and substantially constant from approximately 20 μm and greater.

In addition, a device with a stripe width of W3=200 μm, which is not shown in FIG. 8, indicated that it has substantially the same beam radiation angle as that of the device with a stripe width of W3=55 μm. As described above, in conventional infrared broad stripe multimode semiconductor lasers, it has been difficult to control the beam radiation angle even with the index guiding structure. In particular, it has been difficult to realize a narrow beam radiation angle for higher luminance.

The research conducted by the inventors of the present invention, however, revealed that GaN system stripe type semiconductor lasers, which also produce higher mode or multimode oscillation in the transverse mode, have quite different characteristics. That is, the research revealed that a smaller effective index difference Δn between the central region of the stripe and outside of the stripe provides a narrower horizontal beam radiation angle in the GaN system stripe type semiconductor lasers. Further, a stable index guiding is also obtained in a wide range of Δn, which proves that it is well suited for practical use.

FIG. 2 shows the research results indicating the relationship between the effective index difference Δn between the central region of the stripe and outside of the stripe, and the horizontal beam radiation angle (full width at half maximum) for typical examples of GaN system stripe type semiconductor laser devices which produce higher mode or multimode oscillation in the transverse mode. FIG. 2 indicates that a substantially small horizontal radiation beam angle of not greater than 200 is obtained when the effective index difference Δn is in the range of not greater than 1.5×10⁻².

Generally, smaller effective index difference Δn results in less stable index guiding. In this case, however, it was verified that a stable index guiding is obtained even at a comparatively small effective index difference Δn of 5×10⁻³, which allows steady control of the transverse mode. Thus, from this perspective, in the semiconductor laser constituting the present invention, it is preferable that the effective index difference Δn is set at a value in the range of 5×10⁻³≦Δn≦1.5×10⁻².

Further, if the value of the effective index difference Δn is in the range of 1×10⁻² and below, the horizontal beam radiation angle becomes further narrower around 15° or below, which allows further increase in the luminance. Thus, from this perspective, in the semiconductor laser constituting the present invention, it is more preferable that the effective index difference Δn is set at a value in the range of 5×10⁻³≦Δn≦1×10⁻².

FIG. 3 shows the research results indicating the relationship between the stripe width W1 and the horizontal beam radiation angle (full width at half maximum) for typical examples of GaN system stripe type semiconductor laser devices which produce higher mode or multimode oscillation in the transverse mode. FIG. 3 indicates that the horizontal beam radiation angle is independent of the stripe width W1, if it is in the range shown in the Figure. If that is the case, it is preferable to realize a high output power by providing a broad stripe with the width W1 of not less than 5 μm.

For comparison purpose, FIG. 3 also shows the similar relationship for semiconductor lasers with a stripe width of W1=1.4 μm that oscillate in the fundamental transverse mode. FIG. 3 indicates that the broad stripe transverse multimode semiconductor lasers have significantly larger beam radiation angles, and have quite different beam radiation characteristics compared with the fundamental transverse mode semiconductor lasers.

In the mean time, each of the semiconductor laser devices according to the present invention is constructed to combine a plurality of near-field patterns ranging in a direction parallel to the junction surface. There, the semiconductor laser chips having a substantially small horizontal beam radiation angle are used, so that in each of the semiconductor laser devices, the number of beams n to be combined may be increased. This allows a high power and high luminance output to be realized.

### BRIEF DESCRIPTION OF THE DRAWINGS

FIG. 1 is a schematic cross-sectional view of a semiconductor laser chip according to an embodiment of the present invention.

FIG. 2 is a drawing illustrating the relationship between the horizontal beam radiation angle and effective index difference between inside and outside of the stripe for GaN system broad stripe transverse multimode semiconductor lasers.

FIG. 3 is a drawing illustrating the relationship between the horizontal beam radiation angle and stripe width for GaN system broad stripe transverse multimode semiconductor lasers.

FIG. 4 is a schematic plan view of an example of semiconductor laser device that combines and focuses laser beams.

FIG. 5 is a schematic plan view of another example of semiconductor laser device that combines and focuses laser beams.

FIG. 6 is a schematic vertical cross-sectional view of an example of existing infrared semiconductor laser.

FIG. 7 is a drawing illustrating the relationship between the horizontal beam radiation angle and effective index difference between inside and outside of the stripe for existing infrared semiconductor lasers.

FIG. 8 is a drawing illustrating the relationship between the horizontal beam radiation angle and stripe width for existing infrared semiconductor lasers.

### DESCRIPTION OF THE PREFERRED EMBODIMENTS

Hereinafter, embodiments of the present invention will be described in detail with reference to the accompanying drawings.

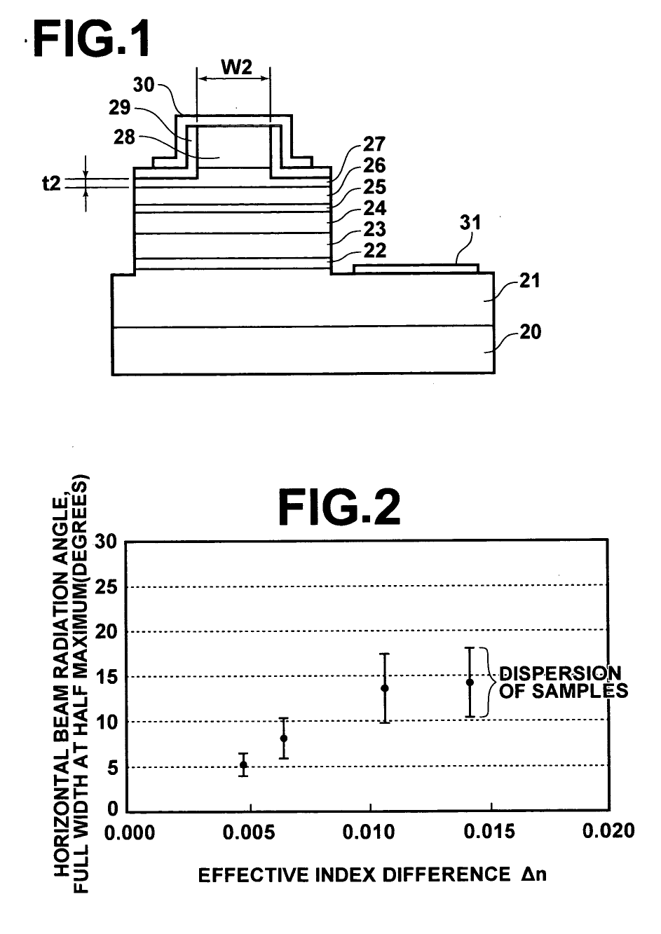

FIG. 1 is a schematic cross-sectional view of a semiconductor laser that constitutes an embodiment of the present invention. As shown in FIG. 1, the semiconductor laser includes: a low-defect GaN substrate 20; an n-GaN buffer layer 21 (Si doped, 5 μm thickness). It further includes: an n-In_{0.1}Ga_{0.9}N buffer layer 22 (Si doped, 0.1 μm thickness); an n-Al_{0.1}Ga_{0.9}N clad layer 23 (Si doped, 0.45 μm thickness); an n-GaN optical guide layer 24 (Si doped, 0.1 μm thickness); an undoped active layer 25; a p-GaN optical guide layer 26 (Mg doped, 0.3 μm thickness); a p-Al_{0.1}Ga_{0.9}N clad layer 27 (Mg doped, 0.45 μm thickness); and p-GaN cap layer 28 (Mg doped, 0.25 μm thickness), which are sequentially layered on the n-GaN buffer layer 21.

The periphery of the p-GaN cap layer 28 and upper surface of the p-Al_{0.1}Ga_{0.9}N clad layer 27 is covered by a SiN film 29. A p-electrode 30 made of Ni/Au is formed on the SiN film 29, and an n-electrode 31 made of Ti/Al/Ti/Au is formed in the area that does not include the emitting region on the upper surface of the n-GaN buffer layer 21.

Hereinafter, a manufacturing method of the aforementioned semiconductor laser will be described. First, a layer serving as the low-defect GaN substrate 20 is formed on a sapphire C-surface substrate, which is not shown, by a method as described, for example, in “High-Power and Long-Lifetime InGaN Multi-Quantum-Well Laser Diodes Grown on Low-Dislocation—Density GaN Substrates” by Shin-ichi Nagahama, et al., Japanese Journal of Applied Physics, Vol. 39, No. 7A, 2000, pp. L647-L650. Then, the n-GaN buffer layer 21, n-In_{0.1}Ga_{0.9}N buffer layer 22, n-Al_{0.1}Ga_{0.9}N clad layer 23, n-GaN optical guide layer 24, undoped active layer 25, p-GaN optical guide layer 26, p-Al_{0.1}Ga_{0.9}N clad layer 27, and p-GaN cap layer 28 are grown using the atmospheric MOCVD method.

Here, the active layer 25 has a four-layer structure constituted by undoped In_{0.1}Ga_{0.9}N quantum well layer (3 nm thickness), undoped Al_{0.04}Ga_{0.96}N barrier layer (0.01 μm thickness), undoped In_{0.1}Ga_{0.9}N quantum well layer (3 nm thickness), and p-Al_{0.1}Ga_{0.9}N barrier layer (Mg doped, 0.0 μm thickness).

Then, a ridge stripe with a width of W2 is formed by etching the sides of the p-GaN cap layer 28 and p-Al_{0.1}Ga_{0.9}N clad layer 27 to the point away from the upper surface of the p-GaN optical guide layer 26 by the distance of t2 using photolithography and the RIBE (reactive ion beam etching) method with chloride ion.

Then, unnecessary parts are removed by photolithography and etching after the SiN film 29 is coated over the entire surface by the plasma CVD method. Thereafter, a p-type impurity is activated by heat treatment in the presence of nitrogen gas. Then, epi-layers in the areas other than the area that includes the emitting region are removed until the surface of the n-GaN buffer layer 21 is exposed by RIBE method with chloride ion. Thereafter, Ti/Al/Ti/Au as the n-electrode material, and Ni/Au as the P-electrode material are vacuum deposited, and annealed in the presence of nitrogen gas to form the n-electrode 31 and p-electrode 30, which are ohmic electrodes. The end face of the resonator is formed by cleavage.

This produces a GaN system stripe type semiconductor laser of the present embodiment. The semiconductor laser has an index guiding structure, and produces higher mode or multimode oscillation in the transverse mode with the oscillation wavelength of 405 nm.

As described earlier, FIG. 2 shows the research results indicating the relationship between the effective index difference Δn between the central region of the stripe and outside of the stripe, and the horizontal beam radiation angle (full width at half maximum) for the semiconductor lasers of the present embodiment. In this example, four samples were created to examine the aforementioned relationship. The samples have the effective index difference Δn of 4.8×10⁻³, 6.5×10⁻³, 1.07×10⁻², and 1.42×10⁻² respectively with the same ridge stripe wide W2 of 7 μm. The values of the effective index difference Δn were obtained by changing the after-etching residual thickness t2 of the p-A_{0.1}Ga_{0.9}N clad layer 27. FIG. 2 indicates that a substantially small horizontal beam radiation angle of not greater than 200 is obtained when the effective index difference Δn is in the range of not greater than 1.5×10⁻².

Generally, smaller effective index difference Δn results in less stable index guiding. In this case, however, it was verified that a stable index guiding is obtained even at a comparatively small effective index difference Δn of 5×10⁻³, which allows steady control of the transverse mode. Thus, from this perspective, it is preferable that the effective index difference Δn is set at a value in the range of 5×10⁻³≦Δn≦1.5×10⁻².

Further, if the value of the effective index difference Δn is in the range of 1×10⁻² and below, the horizontal beam radiation angle becomes further narrower around 150 or below, which allows further increase in the luminance. Thus, from this perspective, it is more preferable that the effective index difference Δn is set at a value in the range of 5×10⁻³≦Δn≦1×10⁻².

FIG. 3 shows the research results indicating the relationship between the stripe width W1 and the horizontal beam radiation angle (full width at half maximum) for the semiconductor lasers of the present embodiment. In this example, three samples were created to examine the aforementioned relationship. The samples have the stripe width W1 of 5, 10, and 15 μm respectively with the same effective index difference Δn of 9×10⁻³. As described earlier, FIG. 3 indicates that the horizontal beam radiation angle is independent of the stripe width W1, if it is in the range from 5 to 15 μm. If that is the case, it is preferable to realize a high output power by providing a broad stripe with the width W1 of not less than 5 μm.

The semiconductor laser having a basic structure which is identical to that of the present embodiment may be produced using an insulating sapphire substrate other than the GaN substrate used in the present embodiment. Further, the identical structure may be formed on a conductive substrate such as SiC or the like. Still further, AlGaN embedded structures, other index guiding structures, and current constriction structures may also be used.

Further, in the present embodiment, the clad layer is made of Al_{0.1}Ga_{0.9}N, and optical guide layer is made of GaN. Al composition of the clad layer needs to be 0.1 or greater in order to obtain the carrier containment effect. The light containment effect increases with increase in the Al composition in the range of 0.1 and greater. Thus, the Al composition of 0.1 is a sufficient condition, and satisfactory light containment may be realized using a thin AlGaN clad layer. In addition, as for the clad layer, a superlattice structure that includes AlGaN or the like may also be applied.

Still further, the semiconductor laser of the present embodiment may be produced by cleaving the substrate such that a single stripe structure is formed on a single semiconductor chip. It is also possible to produce a semiconductor laser array by cleaving the substrate such that a plurality of stripe structures is formed on a single semiconductor chip.

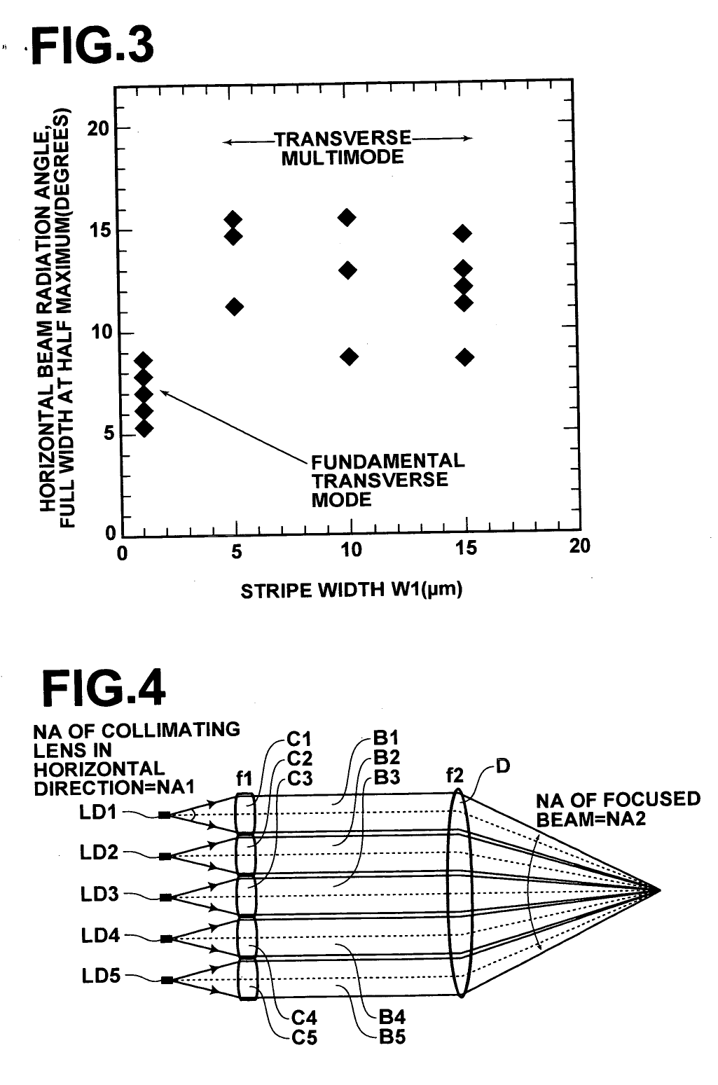

Hereinafter, embodiments of the beam-combining semiconductor laser device will be described. First, an embodiment that uses a plurality of semiconductor laser chips of the type shown in FIG. 1, that is, semiconductor laser chips, each with a single stripe structure, may be cited as one of the embodiments. The overall structure of the device is basically identical to that shown in FIG. 4. Therefore, the semiconductor laser device of the present embodiment may be provided by simply replacing each of the plurality of semiconductor lasers LD1 to LD5 shown in FIG. 4 with the semiconductor laser chip shown in FIG. 1.

In this case, the plurality of semiconductor laser chips is arranged such that each of the luminous points thereof is aligned substantially in a straight line in a direction which is parallel to the junction surface, and a plurality of near-field patterns ranging in a direction parallel to the junction surface overlaps with each other.

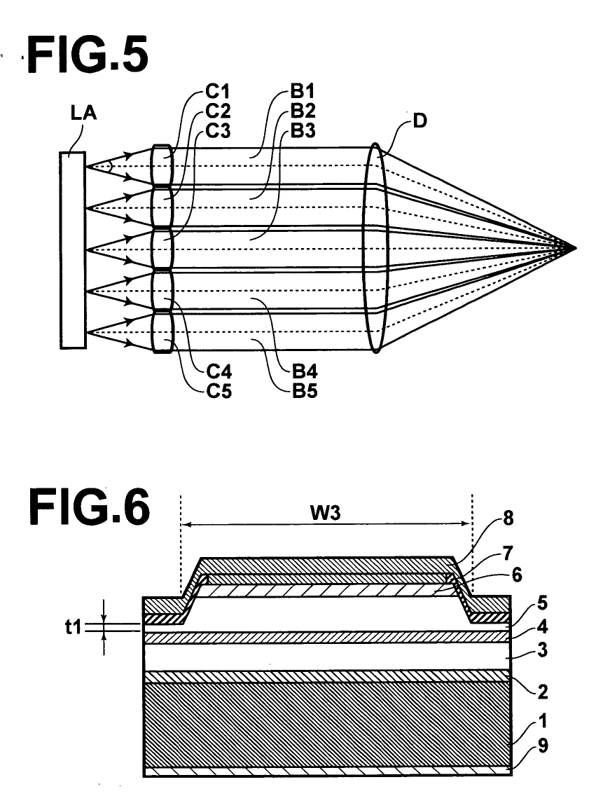

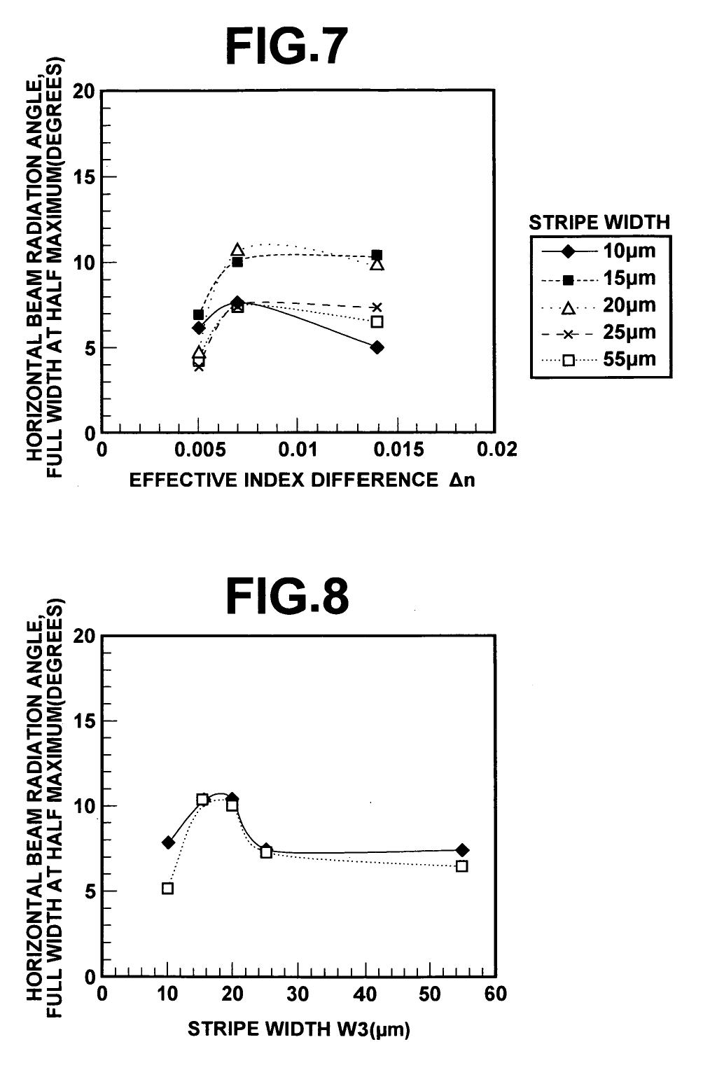

Next, an embodiment that uses a single semiconductor laser array of the present invention, that is, the semiconductor laser array of a single semiconductor chip with a plurality of stripe structures formed thereon may be cited as another embodiment. The overall structure of the device is basically identical to that shown in FIG. 5. Therefore, the semiconductor laser device of the present embodiment may be provided by simply replacing the semiconductor laser array LA shown in FIG. 5 with the semiconductor laser array of the present invention described above.

In the semiconductor laser array described above, a plurality of stripes is formed such that each of the luminous points thereof is aligned substantially in a straight line in a direction which is parallel to the junction surface. In the present embodiment, a plurality of near-field patterns ranging in a direction parallel to the junction surface overlaps with each other through a beam combining and focusing optics system. Further, a plurality of the semiconductor laser arrays arranged side by side may be used to increase the number of beams to be combined.

Each of the semiconductor laser devices described above uses the semiconductor laser chips of the present invention having a small horizontal beam radiation angle as described earlier, which is the characteristic feature of the present invention, so that a high power and high luminance output may be realized by increasing the number of beams n to be combined.

What is claimed is:

1. A GaN system stripe type semiconductor laser apparatus comprising an index guiding structure, and producing higher mode or multimode oscillation in the transverse mode,
wherein the effective index difference Δn between the central region of the stripe and outside of the stripe is not greater than 1.5×10⁻².

2. The semiconductor laser apparatus according to claim 1, wherein the effective index difference Δn is in the range of 5×10⁻³≦Δn≦1.5×10⁻².

3. The semiconductor laser apparatus according to claim 1, wherein the effective index difference Δn is in the range of 5×10⁻³≦Δn≦1×10⁻².

4. The semiconductor laser apparatus according to claim 1, wherein the stripe width is not less than 5 μm.

5. The semiconductor laser apparatus according to claim 2, wherein the stripe width is not less than 5 μm.

6. The semiconductor laser apparatus according to claim 1, wherein the index guiding structure is a ridge waveguide structure.

7. The semiconductor laser apparatus according to claim 2, wherein the index guiding structure is a ridge waveguide structure.

8. The semiconductor laser apparatus according to claim 4, wherein the index guiding structure is a ridge waveguide structure.

9. The semiconductor laser apparatus according to claim 1, wherein the index guiding structure is an inner stripe type waveguide structure.

10. The semiconductor laser apparatus according to claim 2, wherein the index guiding structure is an inner stripe type waveguide structure.

11. The semiconductor laser apparatus according to claim 4, wherein the index guiding structure is an inner stripe type waveguide structure.

12. The semiconductor laser apparatus according to claim 1, wherein the apparatus comprises a single stripe structure formed on a single semiconductor chip.

13. The semiconductor laser apparatus according to claim 2, wherein the apparatus comprises a single stripe structure formed on a single semiconductor chip.

14. The semiconductor laser apparatus according to claim 1, wherein the apparatus comprises a semiconductor laser array, in which a plurality of stripe structures is formed on a single semiconductor chip with each of the luminous points thereof being aligned substantially in a straight line in a direction parallel to the junction surface.

15. The semiconductor laser apparatus according to claim 2, wherein the apparatus comprises a semiconductor laser array, in which a plurality of stripe structures is formed on a single semiconductor chip with each of the luminous points thereof being aligned substantially in a straight line in a direction parallel to the junction surface.

16. A semiconductor laser apparatus comprising:
a plurality of the semiconductor laser chips of the claim 12 arranged such that each of the luminous points thereof is aligned substantially in a straight line in a direction parallel to the junction surface;
a plurality of collimating lenses, each for collimating each of the laser beams emitted from each of the semiconductor laser chips; and
a condenser lens for focusing a plurality of the laser beams transmitted through the collimating lenses on a substantially common point.

17. A semiconductor laser apparatus comprising:
a plurality of the semiconductor laser chips of the claim 13 arranged such that each of the luminous points thereof is aligned substantially in a straight line in a direction parallel to the junction surface;
a plurality of collimating lenses, each for collimating each of the laser beams emitted from each of the semiconductor laser chips; and
a condenser lens for focusing a plurality of the laser beams transmitted through the collimating lenses on a substantially common point.

18. A semiconductor laser apparatus comprising:
a single or a plurality of the semiconductor laser chips of the claim 14;
a plurality of collimating lenses, each for collimating each of the laser beams emitted from the semiconductor laser chip or chips; and
a condenser lens for focusing a plurality of the laser beams transmitted through the collimating lenses on a substantially common point.

19. A semiconductor laser apparatus comprising:
a single or a plurality of the semiconductor laser chips of the claim 15;
a plurality of collimating lenses, each for collimating each of the laser beams emitted from the semiconductor laser chip or chips; and
a condenser lens for focusing a plurality of the laser beams transmitted through the collimating lenses on a substantially common point.
